(19) United States
(12) Patent Application Publication
(10) Pub. No.: US 2016/0229689 A1
(43) Pub. Date: Aug. 11, 2016

(54) Packaged Microchip with Patterned Interposer

(71) Applicant: Analog Devices, Inc., Norwood, MA (US)

(72) Inventors: Bradley C. Kaanta, Belmont, MA (US); John A. Alberghini, Burlington, MA (US); Kemiao Jia, Tolland, CT (US)

(21) Appl. No.: 15/004,252

(22) Filed: Jan. 22, 2016

Related U.S. Application Data
(60) Provisional application No. 62/114,741, filed on Feb. 11, 2015.

(51) Int. Cl. B81B 7/00; B81C 1/00

(52) U.S. Cl. CPC B81B 7/0048; B81C 1/00269

(57) ABSTRACT

A packaged microchip has a base, a die with a mounting surface, and an electrically inactive interposer between the base and the die. The interposer has a first side with at least one recess that extends no more than part-way through the interposer from the first side. Accordingly, the recess defines a top portion (of the first side) with a top area. The die mounting surface, which is coupled with the interposer, correspondingly has a die area. The top area of the interposer preferably is less than the die area.

### PRIORITY

This patent application claims priority from Provisional U.S. Patent Application No. 62/114,741, filed Feb. 11, 2015, entitled, “MEMS DEVICE WITH PATTERNED INTERPOSER,” and naming Bradley C. Kaanta, John A. Alberghini, and Kemiao Jia as inventors, the disclosure of which is incorporated herein, in its entirety, by reference.

### FIELD OF THE INVENTION

The disclosure generally relates to microchips and, more particularly, the disclosure relates to packaging techniques for microchips.

### BACKGROUND OF THE INVENTION

Microelectromechanical systems (“MEMS”) are used in a growing number of applications. For example, MEMS currently are implemented as gyroscopes to detect pitch angles of airplanes, and as accelerometers to selectively deploy air bags in automobiles. In simplified terms, such MEMS devices typically have a structure suspended above a substrate, and associated electronics that both senses movement of the suspended structure and delivers the sensed movement data to one or more external devices (e.g., an external computer). The external device processes the sensed data to calculate the property being measured (e.g., pitch angle or acceleration).

The associated electronics, substrate, and movable structure typically are formed on one or more dies (referred to herein simply as a “die”) that are secured within a package. For example, the package, which typically protects the die, may be produced from any number of materials, such as ceramic or plastic. The package includes interconnects that permit the electronics to transmit the movement data to the external devices. To secure the die to the package interior, the bottom surface of the die commonly is bonded (e.g., with an adhesive or solder) to an internal surface of the package. Accordingly, substantially all of the area of the bottom die surface is bonded to the internal surface the package.

Problems can arise, however, when the temperatures of the two surfaces change. In particular, because both surfaces typically have different coefficients of thermal expansion, the package can apply a mechanical stress to the substrate of the die. This stress undesirably can bend or flex the substrate to an unknown curvature. Substrate bending or flexing consequently can affect movement of the die structures and the functioning of the electronics, thus causing the output data representing the property being measured (e.g., acceleration) to be erroneous. In a similar manner, mechanically induced linear or torsional stress applied to the package also can be translated to the die, thus causing the same undesirable effects.

SUMMARY OF VARIOUS EMBODIMENTS

In accordance with one embodiment of the invention, a packaged microchip has a base, a die with a mounting surface, and an electrically inactive interposer between the base and the die. The interposer has a first side with at least one recess that extends no more than part-way through the interposer from the first side. Accordingly, the recess defines a top portion (of the first side) with a top area. The die mounting surface, which is coupled with the interposer, correspondingly has a die area. The top area of the interposer preferably is less than the die area.

The top surface of the interposer can be mounted to either the die or the base. To that end, the mounting surface of the die may couple with the first side of the interposer. Alternatively, the first side of the interposer may couple with the base. Moreover, adhesive may couple the interposer to the base and/or the die. For example, adhesive may be within the at least one recess to connect the interposer to the base or the die. In this case, at least a part of the top portion of the interposer may directly contact the base or the die mounting surface (i.e., substantially no adhesive between that portion and the surface it directly contacts). As another example, a very thin adhesive film may be positioned on the top portion of the interposer. In that latter case, the adhesive film connects the interposer to the base or the die.

As an electrically inactive element, the interposer is configured not to electrically connect the die and the base. In addition, the die can implement any of a variety of types of dice. For example, the MEMS may include MEMS microstructure protected by a lid coupled with the base.

To further mitigate the adverse effects of stress, the top area may be less than half of the die area. The coefficients of thermal expansion (“CTE”) of the elements of the packaged microchip also may be selected to further mitigate stress. As such, the die may have a die CTE that is substantially equal to the interposer CTE. In related embodiments, the interposer CTE may be between the die CTE and base CTE.

In accordance with another embodiment, a method of forming a packaged microchip couples an electrically inactive interposer between a base and a die. The interposer has a first side with at least one recess that defines a top portion with a top area. The at least one recess extends no more than part-way through the interposer from the first side. The die has a mounting surface, coupled with the interposer, having a die area. The top area of the interposer is less than the die area.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a system that may use a packaged microchip configured in accordance with illustrative embodiments of the invention.

FIG. 2A schematically shows a view of a microchip that may be configured in accordance with illustrative embodiments of the invention.

FIG. 2B schematically shows a cross-sectional view of the microchip of FIG. 2A.

FIG. 3A schematically shows a view of another microchip that may be configured in accordance with illustrative embodiments of the invention.

FIG. 3B schematically shows a cross-sectional view of the microchip of FIG. 3A.

FIG. 4 schematically shows an interposer configured in accordance with illustrative embodiments of the invention.

FIG. 5 schematically shows a top view of the interposer of FIG. 4.

FIGS. 6A-6C respectively show perspective, top, and side views of an interposer configured in accordance with another embodiment of the invention.

FIGS. 7 through 12 schematically show several different recess examples that may be used with illustrative embodiments of the invention.

FIG. 13 shows a process of forming a packaged microchip in accordance with illustrative embodiments of the invention.

### DESCRIPTION OF ILLUSTRATIVE EMBODIMENTS

In illustrative embodiments, a packaged microchip has an intermediate structure positioned between its die and package base to mitigate and/or redirect undesirable stress transmitted to the die from the base. To that end, the intermediate structure has one or more faces formed with recessed surfaces. Details of illustrative embodiments are discussed below.

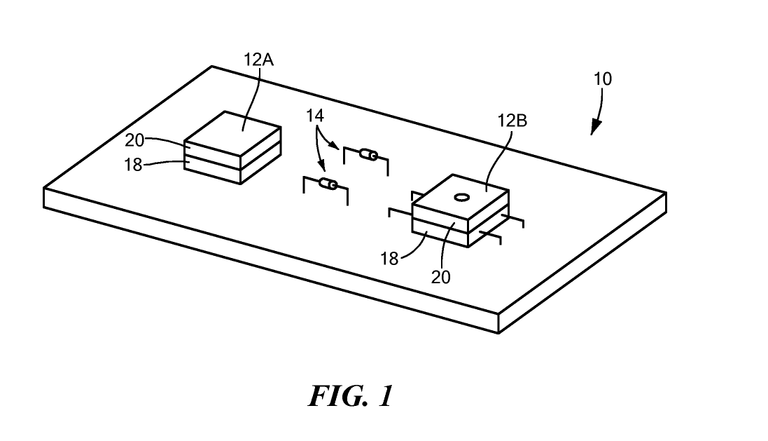

FIG. 1 schematically shows a printed circuit board 10 having packaged microchips configured in accordance with illustrative embodiments of the invention. This printed circuit board 10 may be part of a larger system, such as an automobile airbag system, a transducer system, a guidance system, a computer system, or other application. To those ends, the printed circuit board 10 supports and connects a plurality of different circuit components identified in the drawing by reference numbers 12A, 12B, and 14 (discussed below) in the prescribed manner. FIG. 1 shows only a few exemplary components 12A, 12B, and 14 for simplicity.

The components 12A, 12B, and 14 shown include a first packaged microchip 12A surface mounted to the printed circuit board 10, a second packaged microchip 12B, and other active or passive circuit components (generally identified by reference number “14”). Among other things, the first and second packaged microchips 12A and 12B each may include one or more MEMS dice (see subsequent figures) having microstructure integrally formed with the substrate, and circuitry that cooperates with the microstructure. In illustrative embodiments, the integral structure is formed using conventional micromachining processes, which use additive and/or subtractive processes to form a generally monolithic die/substrate.

Among other things, the first packaged microchip 12A may be an inertial sensor, such as a MEMS accelerometer or MEMS gyroscope, a MEMS optical switch, or a MEMS electrostatic switch. Exemplary MEMS gyroscopes are discussed in greater detail in U.S. Pat. No. 6,505,511, which is assigned to Analog Devices, Inc. of Norwood, Mass. Exemplary MEMS accelerometers are discussed in greater detail in U.S. Pat. No. 5,939,633, which also is assigned to Analog Devices, Inc. of Norwood, Mass. The disclosures of U.S. Pat. Nos. 5,939,633 and 6,505,511 are incorporated herein, in their entireties, by reference.

The second packaged microchip 12B may include functionality that requires access to the ambient environment, but still requires some environmental protection. For example, the second packaged microchip 12B may include a microphone or pressure sensor. As noted, one or both of the devices 12A and 12B may include circuitry, such as that included in IMEMS devices distributed by Analog Devices, Inc.

Unlike the first packaged microchip 12A, the second packaged microchip 12B has pins to electrically connect to the printed circuit board 10. Either type of electrical interconnect method should suffice for various embodiments. In illustrative embodiments, each package is formed from a base 18 and lid 20 that together form a package chamber for securing the microchip. In the example of a MEMS die, the package chamber may contain the MEMS die alone, or with additional circuitry, such as an application specific integrated circuit.

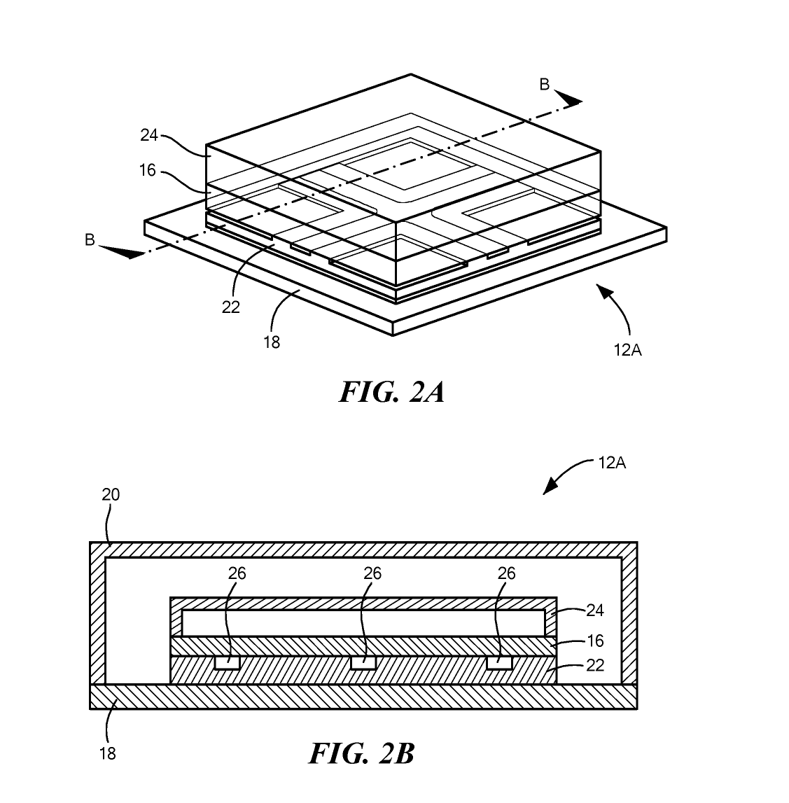

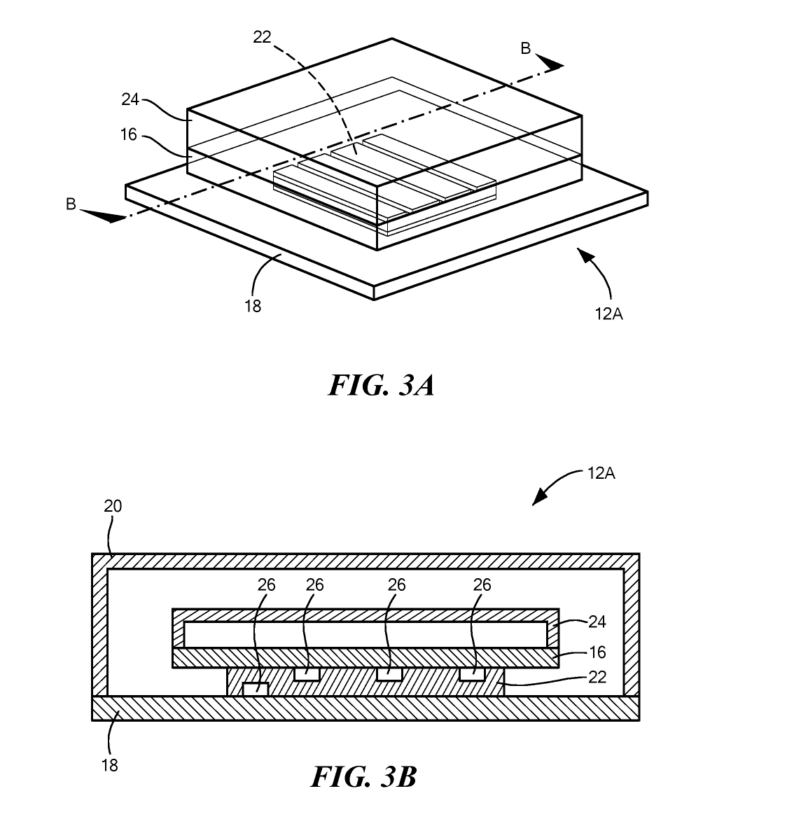

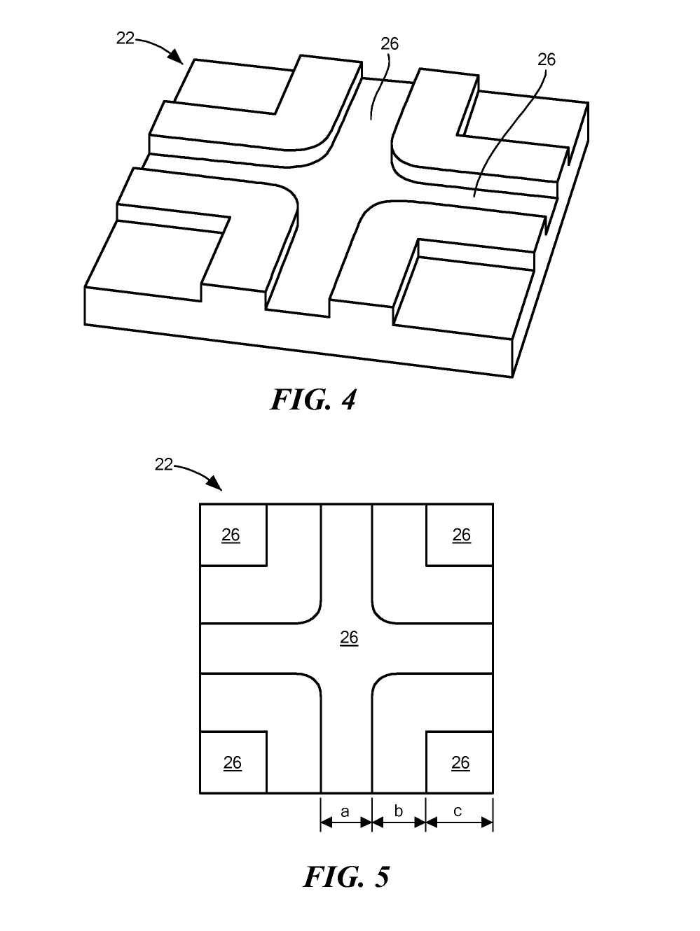

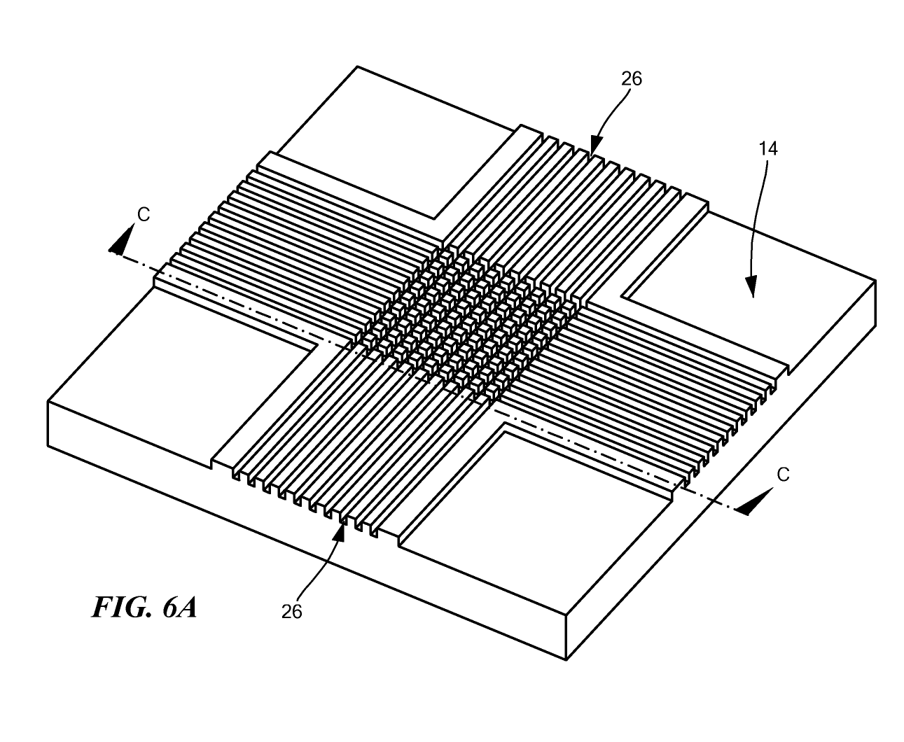

FIG. 2A schematically shows a view of the first packaged microchip 12A configured in accordance with illustrative embodiments of the invention. Unlike FIG. 1, however, this figure (and FIG. 3A, below) does not show the lid 20 to better show the other elements. The first packaged microchip 12A preferably includes a MEMS die 16 (although it may be another type of die) forming one layer of a stack of structures. In this case, those structures include a package base 18 supporting the stack, an intermediate, stress-reducing structure, referred to as an “interposer 22,” having a bottom side secured to the base 18, and the noted MEMS die 16, with specified functionality (e.g., inertial sensing functionality), secured to the top side of the interposer 22. The packaged microchip 12A also has a cap 24 secured to the top surface of the die 16.

FIG. 2A (and FIG. 3A, below) schematically shows the MEMS die 16 as a semi-transparent block to permit a more clear view of the interposer 22. Those skilled in the art should understand that the MEMS die 16 is a solid component. Accordingly, the arrow pointing to the interposer 22 in FIG. 1 is intended to point through the MEMS die 16.

Some embodiments may omit the lid 20 entirely. In such embodiments, the cap 24 alone may provide appropriate environmental protection for the die 16.

The MEMS die 16 may be formed using any of a variety of materials. For example, the MEMS die 16 may implement an accelerometer having a conventional single crystal silicon substrate supporting fragile and highly sensitive microstructure. Illustrative embodiments bond the cap 24 to the substrate to form an interior die chamber that hermetically seals and protects the fragile microstructure. The interior chamber also may include a seal gas to buffer the microstructure, or form a vacuum. Other embodiments do not cap the substrate and thus, rely on the larger package to protect the MEMS microstructure. In those embodiments, the package chamber may contain the seal gas, if seal gas is used.

To mitigate stress caused by thermal changes, illustrative embodiments form the interposer 22 from a material having a coefficient of thermal expansion (“CTE”) that is the same as, or very close to, that of silicon. Accordingly, the interposer 22 preferably may be formed from silicon. For example, the interposer 22 may be formed from a single crystal bulk silicon wafer that is patterned and diced to form the interposer 22. Other embodiments may form the interposer 22 from a material having a comparable CTE to that of silicon. For example, the interposer 22 may be formed from a ceramic material having a CTE similar to that of silicon. The interposer 22 also may be formed from a material having the CTE of the base 18 and/or the die 16 if those components 12 and 16 are not formed from silicon, or another material having a CTE similar to that of silicon.

Other embodiments may form the interposer 22 from a material with a CTE (or from a plurality of materials with a collective CTE) that is different from that of the base 18 and/or the die 16. For example, the interposer 22 may have a CTE that is between the CTEs of the base 18 and the die 16. In the case of a silicon-based die 16, the material would have a different CTE than that of silicon. In some embodiments, the interposer 22 also is formed from a material with a lower Young's Modulus, which should help reduce stress transfer from the base 18 toward the die 16.

Like the die 16, the base 18 may be formed from any of a variety of materials. For example, the base 18 may be formed from a printed circuit board material (e.g., FR-4), ceramic, an application specific integrated circuit (“ASIC”), or a lead frame (e.g., a premolded lead frame). Together with other components, such as the lid 20, the base 18 preferably forms a cavity package that protects the MEMS die 16 from the environment.

FIG. 2B schematically shows a cross-sectional view of FIG. 2A across line B-B of FIG. 2A. As shown, the interposer 22 has an upper surface (a “top portion”) defined by recesses 26 extending part-way through the thickness of the interposer 22 (discussed in greater detail below). The recesses 26 thus may be considered to define a plurality of mesas (i.e., the noted upper surface) that terminate in a higher plane (from the perspective of the figures) than that of the bottom surfaces of the recesses 26. The recesses 26 thus form depressed regions that are not part of the upper surface. In preferred embodiments, the upper surface forms a single plane for receiving the die 16. Accordingly, in the first packaged microchip 12A, the upper surface of the generally discontinuous interposer 22 directly contacts the bottom surface of the die 16 (i.e., the “mounting surface” of the die 16, in this case) within the package chamber. As discussed below, adhesive or other material within the recesses 26 or on the upper surface secures the die 16 to the interposer 22.

The recesses 26 have the effect of reducing the contact area between the interposer 22 and the surface to which it is attached (e.g., the die bottom surface of the first packaged microchip 12A). This reduced contact area mitigates stress transmission between the base 18 and the die 16, effectively improving performance.

In this embodiment of FIGS. 2A and 2B, the interposer 22 may have the same footprint as that of the die 16. In other words, the interposer 22 has an outer perimeter with a shape and size that is substantially the same as that of the die 16. Despite having the same footprint, however, the total surface area of the upper surface of the interposer 22 is less than that of the bottom surface of the die 16. For example, the recesses 26 may be configured so that the upper surface collectively has a total upper surface area that is about fifty percent of that of the surface to which it contacts (e.g., the area of the bottom of the die 16). In other embodiments, the total upper surface area is less than about half that of the surface to which it contacts. In other embodiments, however, the die 16 may have a different footprint than that of the die 16. Regardless of the relative footprint sizes, the total area of the upper surface preferably is less than that of the surface it contacts (e.g., fifty percent or less).

Rather than contacting the die with the interposer surface having recesses, some embodiments orient the interposer 22 so that the upper surface of the embodiment of FIG. 2B contacts the base 18. In other words, the interposer 22 is flipped 180 degrees relative to its position in FIG. 2B. Accordingly, the interposer 22 may mitigate stress by contacting the recessed surface with either the base 18 or the die 16. In fact, some embodiments may have recesses 26 on both the top and bottom surfaces of the interposer 22 (from the perspective of the drawings).

To that end, FIGS. 3A and 3B schematically show an embodiment in which the interposer 22 has recesses 26 on both of its top and bottom surfaces. In addition, this embodiment also has a smaller width and length than that of the embodiment of FIG. 1. Accordingly, the die 16 overhangs the interposer 22—i.e., the die 16 has one or more far portions that do not contact either the interposer 22 or the base 18.

It should be noted that features of FIGS. 2A and 2B may be implemented with features of FIGS. 3A and 3B. For example, the interposer 22 may have the same footprint as that of the die 16, and yet have recesses 26 on both its top and bottom surfaces. Accordingly, discussion of various features with regard to a single embodiment is not intended to exclude other embodiments from having those features.

As noted above, changing temperatures or torsional stress can cause the base 18 to transmit stress toward the MEMS die 16. Illustrative embodiments mitigate the impact of that stress by specially configuring the interposer 22 with the recesses 26, which are configured to redirect and/or mitigate transmission of the stress from the base 18 to the substrate of the MEMS die 16.

To that end, the top surface of the interposer 22 has some prescribed recess pattern that controls stress transmission from the base 18 to the substrate of the MEMS die 16. This pattern preferably is designed based on the features of the die 16. For example, if the die 16 has MEMS microstructure with high stress-sensitive regions (e.g., regions with anchors), then the pattern may direct stress away from these high stress-sensitive regions. Some embodiments may simply direct the stress to a region of the die 16 that can handle the stress, toward the edge of the die 16, and/or away from the edge of the die 16.

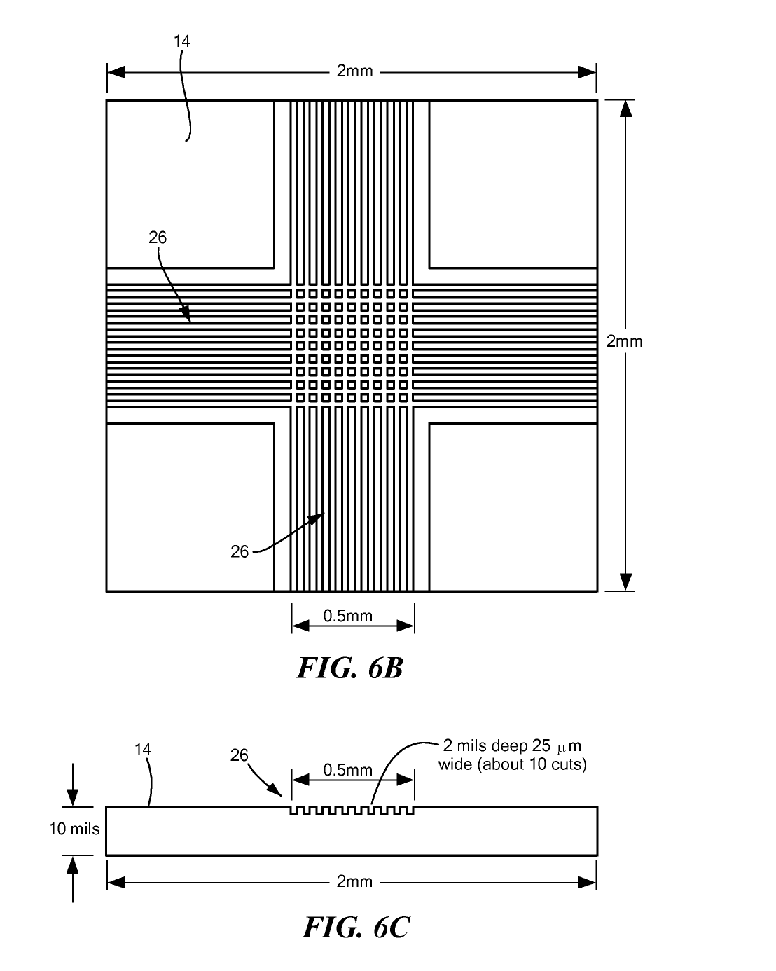

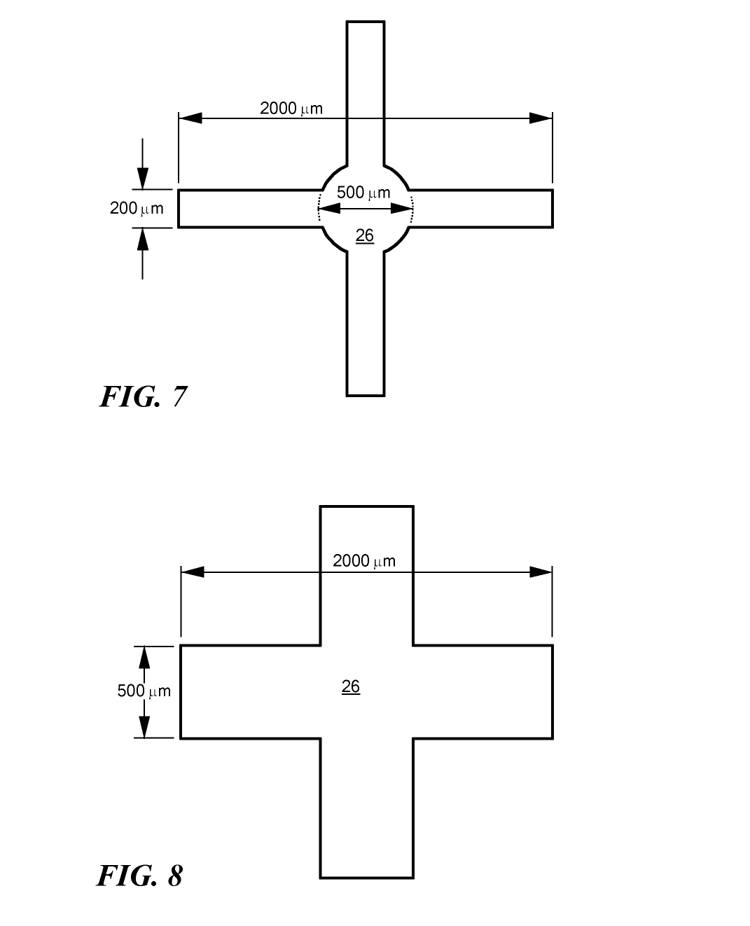

FIG. 4 shows a perspective view of one implementation of such an interposer 22, while FIG. 5 shows a partial plan view of the same interposer 22. This interposer 22 may be used in the embodiment of FIGS. 2A and 2B. As shown, the interposer 22 is considered to have two large, opposed surfaces. One surface forms recesses 26 that effectively define the noted upper surface. When assembled, one of those surfaces contacts the base 18 while the other, unrecessed surface, contacts the die 16. As noted above, although only one side of the die 16 is recessed, one or both of those surfaces may be configured with a pattern such as that shown in FIGS. 4 and 5.

Those skilled in the art would consider preferred embodiments of the interposer 22 to be electrically inactive. Specifically, the interposer 22 has a main body with no added circuitry, including active and passive circuit elements, vias, or traces, that are operating (i.e., not transmitting charge) during use of the first packaged microchip 12A. For example, although the interposer body itself may be formed from a conductive material, such an interposer body has no circuits that electrically interact with circuitry on the die 16 during use, and/or it does not electrically connect the die 16 to the base 18. In fact, illustrative embodiments of the interposer 22 are configured not to electrically connect the die 16 with the base 18. Instead, other components may electrically connect the die 16 with the base 18 (not through the interposer 22), if necessary. For example, wirebonds may extend from die pads to pads on the base 18. Thus, the body itself may be conductive, and still be electrically inactive. Such an interposer 22 does not electrically interact with circuitry on the die 16 (acting as ground is not considered electrically interacting with circuitry in these embodiments) and does not connect the die 16 with the base 18.

The specific pattern of FIGS. 4 and 5 is but one example of a wide variety of different patterns and thus, should not be construed to limit various embodiments of the invention. As noted above, those skilled in the art can select the appropriate pattern for their application. For example, the position of the microstructure relative to the substrate may dictate an optimal pattern. Specifically, there may be regions of the die 16 that can withstand stress better than other die regions. Accordingly, the recess pattern may direct more of the anticipated stress to those regions than to other regions that may be more susceptible to stress (e.g., portions supporting anchors or stationary microstructure).

As shown and noted above, the patterned surface is considered to form a recessed region, and an elevated region (the prior noted upper surface). The recessed region may be discontinuous or continuous. This is exemplified by the pattern of FIGS. 4 and 5, which show four separate recesses 26 at the corners of the interposer 22, and a center recess 26 forming the shape of a cross having smoothed internal edges. The elevated region/upper surface preferably is substantially flat to provide a level contact surface with the bottom of the die substrate, or the top of the base 18, whichever the case may be. In effect, the elevated region may be considered to form a plateau or mesa of the interposer 22.

Those skilled in the art can select an appropriate shape, width, length, and depth for the recessed region. For example, one of the recesses 26 may have a depth from the top of the elevated region to its bottom of between 25 and 50 percent of the largest thickness of the interposer 22 itself. The recess widths can be relatively wide, such as on the order of 5-15 percent of the total interposer 22 width. Various dimensions are in the figures as examples. Those dimensions, however, are not intended to limit various embodiments.

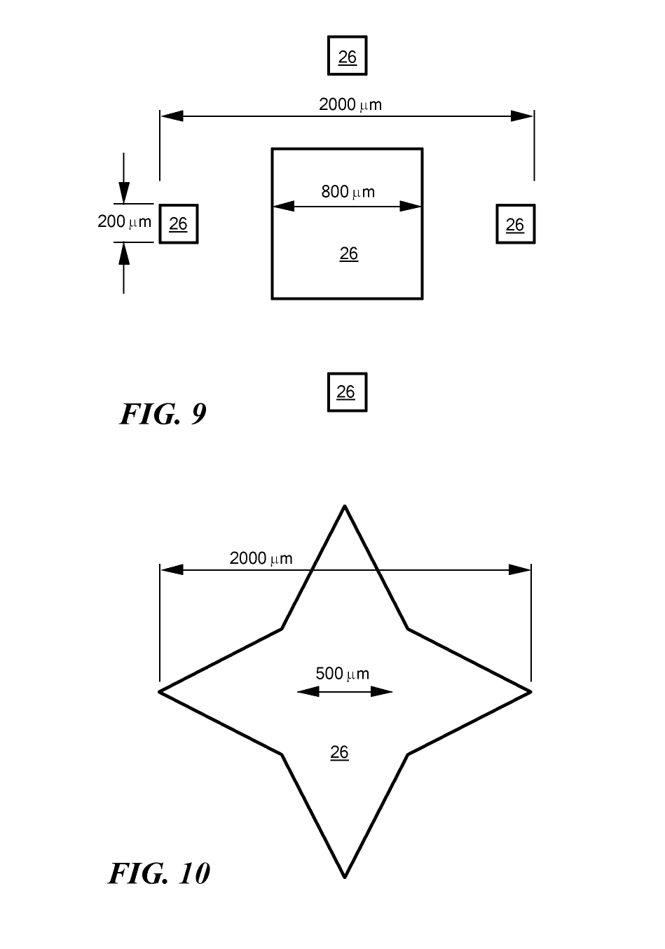

FIGS. 6A through 6C schematically show another embodiment, in which the recesses 26 collectively are relatively large, but are individually very narrow. In this case, the recesses 26 may in the aggregate effectively form a cross-shape similar to that shown in FIGS. 4 and 5. In the example of FIGS. 6A-6C, the interposer 22 is about 2 mm×2 mm square, with a plurality of recesses 26 that alternate about a 0.5 mm width (FIG. 6B). As shown in FIG. 6C (across line C-C of FIG. 6A), this interposer 22 has recesses 26 that each is about 25 microns wide. As also shown in FIG. 6C, the recesses 26 have relatively steep walls and extend about 20 percent into the total thickness of the interposer 22. As shown, the recesses 26 are about 2 mils deep (about 51 microns) while the interposer 22 is about 10 mils thick (about 254 microns). It should be reiterated, however, that the dimensions in these figures are illustrative, and not intended to limit various embodiments.

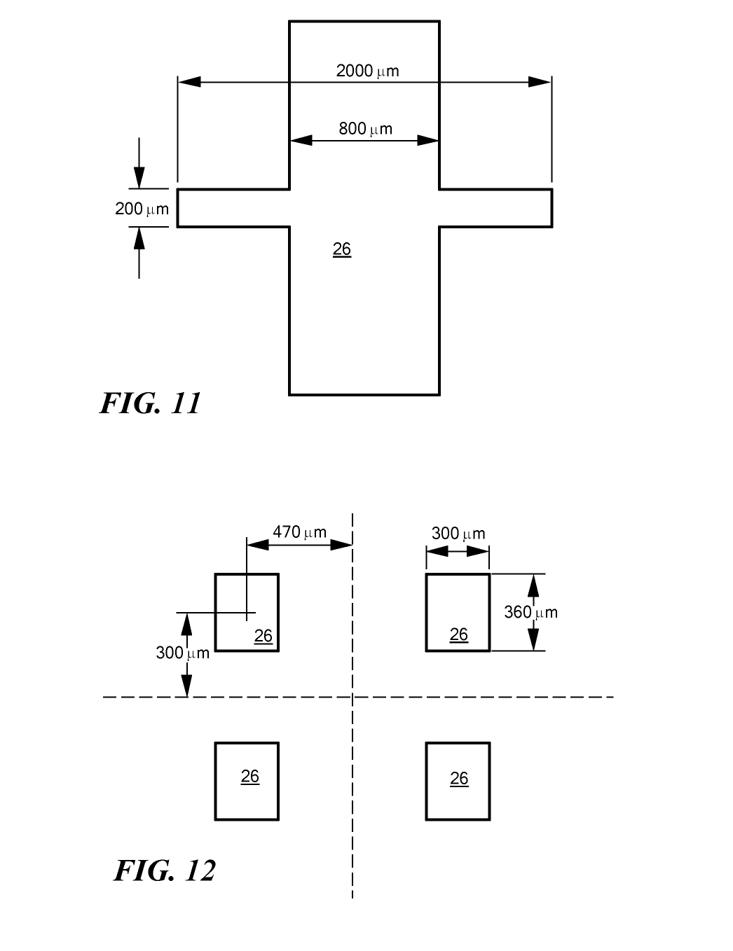

Some embodiments, however, may extend the recesses 26 deeper, such as 50 percent, 60 percent, 70 percent, or 80 percent of the total thickness. Other embodiments may extend some of the recesses all the way though the interposer 22, although such embodiments are not as easy to handle as the partial thickness embodiments and thus, are less desirable. In yet other embodiments, a single recess 26 may have a varying depth (e.g., an irregular or concave bottom surface), or different recesses 26 of the same interposer 22 may have different depths. The recesses 26 can take on a variety of shapes and sizes. For example, the recesses 26 can at least in part be in the form of a trench, channel, groove, rounded dimple, etc. FIG. 7 schematically shows the recess 26 as forming a circle in the middle with four lines extending radially outwardly. FIG. 8 shows a related implementation forming a cross. FIG. 9 schematically shows a discontinuous version of that implementation forming four rectangles/squares that surround a single larger rectangle or square. FIG. 10 schematically shows a diamond pattern, while FIG. 11 schematically shows a thick central trunk having sideways extending side channels. FIG. 12 schematically shows four rectangular blocks in different quadrants of the interposer 22. Again, the dimensions in the figures are for illustrative purposes.

Although the many examples noted above have substantially symmetrical patterns, those skilled in the art can use any of a variety of different patterns that are not symmetrical. Accordingly, discussion of any of the patterns noted above is for exemplary purposes only and not intended to limit various embodiments of the invention.

The interposers 22 discussed above are considered to have two levels; namely, an elevated region (e.g., the noted upper surface) and a recessed region. Some embodiments of the interposer 22 may have more than these two levels. For example, some embodiments may have three or more levels.

The recesses 26 may be formed by any of a wide variety of conventional techniques known in the art. For example, the recesses 26 may be etched, patterned, or otherwise cut into a flat surface of a material, such as a bulk silicon wafer. Alternatively, the recesses 26 may be formed by additive processes that add the elevated region to a generally flat surface of a material, such as a bulk silicon wafer.

Some embodiments position adhesive within the recesses 26 to secure the stack of components together (the adhesive is not shown in the figures to better show other components). In such case, the upper surface preferably is substantially free of adhesive. During assembly of the first packaged microchip 12A, some adhesive may seep onto the upper surface. In such case, at least a portion of the upper surface is substantially free of adhesive. Some implementations may apply a surface treatment to the surface of the upper surface to prevent adhesive from forming on such surface. In these and related embodiments, at least a portion of the upper surface may directly abut or contact the die 16 or base 18, whichever the case may be. In other words, no more than a negligible amount of other material (e.g., adhesive) may separate the upper surface from its corresponding surface on the base 18/die 16. This should assist in leveling the die 16 relative to the upper surface of the interposer 22.

Other embodiments may apply an adhesive to the upper surface only and thus, leave the regions within the recesses 26 substantially free of adhesive. For example, such embodiments may use a thin adhesive film (e.g., a material substrate having an integrated adhesive). As an adhesive film, its application should be substantially uniform, enabling the die 16 to be substantially level.

Either way of applying adhesive should substantially mitigate stress transmission. Some embodiments, however, may apply adhesive to both the recess 26 and the upper surface.

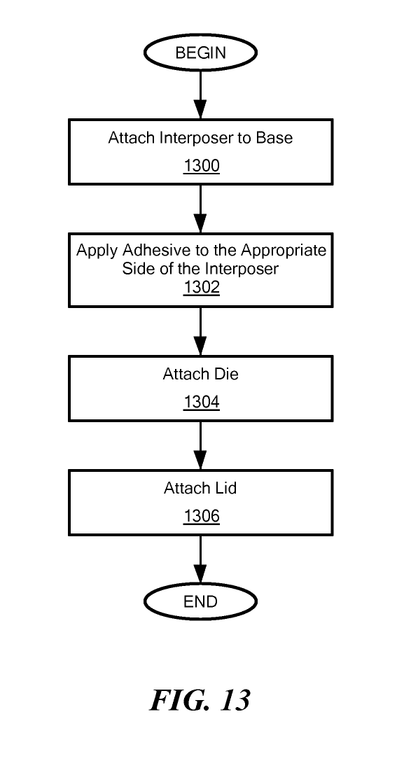

Those skilled in the art can use conventional assembly processes to secure the components together to form the ultimate packaged microchip. FIG. 13 shows a simplified process of forming the first packaged microchip 12A of FIGS. 2A and 2B in accordance with illustrative embodiments. It should be noted that this process is substantially simplified from a longer process that one skilled in the art likely would use to produce the first packaged microchip 12A Accordingly, the process has many steps, such as testing steps, dicing steps, and etching steps (e.g., patterning the interposer 22), which those skilled in the art likely would use. In addition, some of the steps may be performed in a different order than that shown, or at the same time. Those skilled in the art therefore can modify the process as appropriate.

Moreover, as noted above and below, many of the materials and structures noted are but one of a wide variety of different materials and structures that may be used. Those skilled in the art can select the appropriate materials and structures depending upon the application and other constraints. Accordingly, discussion of specific materials and structures is not intended to limit all embodiments.

The process of FIG. 13 preferably uses bulk production techniques, which form a plurality of first packaged microchips 12A on the same base 18 at the same time. Although less efficient, those skilled in the art can apply these principles to a process that forms only one first packaged microchip 12A.

The process begins at step 1300, which attaches the interposer 22 to the base 18. As noted, the process either attaches the upper surface of the interposer 22 to the base 18, or to the bottom surface of the die 16. In this example, the process does not attach the upper surface of the interposer 22 to the base 18. Thus, the process applies an adhesive (e.g., an epoxy) to the bottom, unpatterned surface of the interposer 22, and secures it to the base 18.

After the interposer 22 is in place on the base 18, the process continues to step 1302 by applying adhesive to the appropriate side of the interposer 22—in this case, the top side from the perspective of the drawings. As noted above, the adhesive may be applied to the recesses 26 only using precise adhesive application processes, or to the upper surface with an adhesive or adhesive film. Conventional pick-an-place processes then may place the die 16 on the adhesive (step 1304), and secure the lid 20 to the base 18 (step 1306) as further protection for the first packaged microchip 12A.

Accordingly, the interposer 22 substantially mitigates and/or redirects stress from the base 18, consequently improving device performance.

Although the above discussion discloses various exemplary embodiments of the invention, it should be apparent that those skilled in the art can make various modifications that will achieve some of the advantages of the invention without departing from the true scope of the invention.

What is claimed is:

1. A packaged microchip comprising:
a base;
a die having a mounting surface;
an electrically inactive interposer between the base and the die, the interposer having a first side with at least one recess, the first side having a top portion with a top area, the at least one recess extending no more than part-way through the interposer from the first side,
the mounting surface of the die being coupled with the interposer, the mounting surface having a die area,
the top area being less than the die area.

2. The packaged microchip as defined by claim 1 wherein the mounting surface of the die is coupled with the first side of the interposer.

3. The packaged microchip as defined by claim 1 wherein the first side of the interposer is coupled with the base.

4. The packaged microchip as defined by claim 1 further comprising adhesive within the at least one recess to connect the interposer to the base or the die, at least a part of the top portion of the interposer directly contacting the base or the die mounting surface.

5. The packaged microchip as defined by claim 1 further comprising an adhesive film on the top portion of the interposer, the adhesive film connecting the interposer to the base or the die.

6. The packaged microchip as defined by claim 1 wherein the interposer is configured not to electrically connect the die and the base.

7. The packaged microchip as defined by claim 1 wherein the die comprises MEMS microstructure, the packaged microchip further including a lid coupled with the base.

8. The packaged microchip as defined by claim 1 wherein the top area is less than half of the die area.

9. The packaged microchip as defined by claim 1 wherein the die has a die coefficient of thermal expansion and the interposer has an interposer coefficient of thermal expansion, the die coefficient of thermal expansion being substantially equal to the interposer coefficient of thermal expansion.

10. The packaged microchip as defined by claim 1 wherein the die has a die coefficient of thermal expansion, the interposer has an interposer coefficient of thermal expansion, and the base has a base coefficient of thermal expansion, the interposer coefficient of thermal expansion being between the base coefficient of thermal expansion and the die coefficient of thermal expansion.

11. A packaged microchip comprising:
a base;
a die having a mounting surface;
means for reducing stress between the base and the die, the reducing means having a first side with at least one recess, the first side having a top portion with a top area, the at least one recess extending no more than part-way through the reducing means from the first side,
the mounting surface of the die being coupled with the reducing means, the mounting surface having a die area,
the top area being less than the die area.

12. The packaged microchip as defined by claim 11 wherein the mounting surface of the die is coupled with the first side of the reducing means.

13. The packaged microchip as defined by claim 11 wherein the first side of the reducing means is coupled with the base.

14. The packaged microchip as defined by claim 11 further comprising adhesive within the at least one recess to connect the reducing means to the base or the die, at least a part of the top portion of the reducing means directly contacting the base or the die mounting surface.

15. The packaged microchip as defined by claim 11 further comprising an adhesive film on the top portion of the reducing means, the adhesive film connecting the reducing means to the base or the die.

16. The packaged microchip as defined by claim 11 wherein the reducing means comprises an electrically inactive interposer.

17. A method of forming a packaged microchip, the method comprising:
coupling an electrically inactive interposer between a base and a die, the interposer having a first side with at least one recess, the first side having a top portion with a top area, the at least one recess extending no more than part-way through the interposer from the first side,
the die having a mounting surface that is coupled with the interposer, the mounting surface having a die area,
the top area being less than the die area.

18. The method as defined by claim 17 further comprising securing a lid to the base to form a chamber containing the die and the interposer.

19. The method as defined by claim 17 wherein coupling comprises using an adhesive to couple the mounting surface of the die with the first side of the interposer.

20. The method as defined by claim 17 wherein coupling comprises using an adhesive to couple the first side of the interposer with the base.
